(19) United States
(12) Patent Application Publication
(10) Pub. No.: US 2025/0357730 A1
(43) Pub. Date: Nov. 20, 2025

(54) SEMICONDUCTOR LASER DEVICE

(71) Applicant: Ushio Denki Kabushiki Kaisha, Tokyo (JP)

(72) Inventors: Shintaro MIYAMOTO, Tokyo (JP); Seiji KITAMURA, Tokyo (JP)

(73) Assignee: Ushio Denki Kabushiki Kaisha, Tokyo (JP)

(21) Appl. No.: 19/209,726

(22) Filed: May 15, 2025

(30) Foreign Application Priority Data
May 16, 2024 (JP) 2024-080294

(51) Int. Cl. H01S 5/24; H01S 5/22

(52) U.S. Cl. CPC H01S 5/24; H01S 5/22; H01S 2301/18

(57) ABSTRACT

In a semiconductor laser device, a light shielding groove is formed in an upper cladding layer so as to be adjacent to a bank in a waveguide direction. A surface of the light shielding groove is covered with an insulating layer (not illustrated), and a depth of the light shielding groove reaches an absorption layer that is either a substrate or a buffer layer formed on the substrate.

### BACKGROUND

### 1. Technical Field

The present disclosure relates to a semiconductor laser device.

### 2. Description of the Related Art

A semiconductor laser (LD) is used as a laser pointer light source. In particular, red and infrared LDs are often used as pointer light sources, and blue and green LDs are also used. In recent years, there is an increasing demand for clear visual recognition of a light spot of a pointer or recognition by a sensor or a camera.

When an interference fringe is generated in a far field pattern (FFP, far-field image) that is an image of a laser emitted by a semiconductor laser, a clear light spot cannot be formed.

### SUMMARY

One aspect of the present disclosure has been made in view of the above circumstances, and one exemplary object thereof is to provide a semiconductor laser in which generation of interference fringes in an FFP is suppressed.

One aspect of the present disclosure relates to an edge emitting type semiconductor laser device. A semiconductor laser device includes a multilayer structure of a lower cladding layer, an active layer, and an upper cladding layer formed on a semiconductor substrate, a ridge portion formed in the upper cladding layer, a bank formed in the upper cladding layer so as to be adjacent to the ridge portion in a width direction, and a light shielding groove formed in the upper cladding layer so as to be adjacent to the bank in a waveguide direction.

It is to be noted that any arbitrary combination or rearrangement of the above-described structural components and so forth is effective as and encompassed by the present embodiments. Moreover, all of the features described in this summary are not necessarily required by embodiments so that the embodiment may also be a sub-combination of these described features. In addition, embodiments may have other features not described above.

### BRIEF DESCRIPTION OF THE DRAWINGS

Embodiments will now be described, by way of example only, with reference to the accompanying drawings which are meant to be exemplary, not limiting, and wherein like elements are numbered alike in several Figures, in which:

FIG. 1 is a perspective view of a semiconductor laser device according to an embodiment;

FIG. 2 is a diagram schematically illustrating beam intensity of the semiconductor laser device of FIG. 1;

FIG. 3 is a cross-sectional view perpendicular to an x-axis of the semiconductor laser device of FIG. 1;

FIG. 4 is a diagram describing shielding of stray light by a light shielding groove;

FIG. 5 is a cross-sectional view of a semiconductor laser device according to comparative art;

FIG. 6 is a cross-sectional view of a semiconductor laser device according to a first modification;

FIG. 7 is a cross-sectional view of a semiconductor laser device according to a second modification;

FIG. 8 is a view illustrating a modification of a cross-sectional shape of a light shielding groove in a plane perpendicular to the x-axis;

FIG. 9 is a perspective view of a semiconductor laser device according to a fourth modification;

FIG. 10 is a perspective view of a semiconductor laser device according to a fifth modification;

FIG. 11 is a diagram illustrating three structures of the semiconductor laser device; and

FIG. 12 is a diagram illustrating a calculation value of an error from the Gaussian distribution of a beam profile of each of first to third structures.

### DETAILED DESCRIPTION

### Overview of Embodiment

An overview of some exemplary embodiments of the present disclosure will be described. This overview is intended as a prelude to the detailed description described below or for a basic understanding of the embodiments. This overview describes some concepts of one or more embodiments in a simplified manner, and does not limit the breadth of the invention or disclosure. In addition, this overview is not a comprehensive overview of all possible embodiments and does not limit the essential components of the embodiments. For convenience, “one embodiment” may be used to refer to one embodiment (example or modification) or a plurality of embodiments (examples or modifications) disclosed in the present specification.

### Overview of Embodiment

An edge emitting type semiconductor laser device according to one embodiment includes a multilayer structure of a lower cladding layer, an active layer, and an upper cladding layer formed on a semiconductor substrate, a ridge portion formed in the upper cladding layer, a bank formed in the upper cladding layer so as to be adjacent to the ridge portion in a width direction, and a light shielding groove formed in the upper cladding layer so as to be adjacent to the bank in a waveguide direction. As a result, light propagating from the bank is shielded, and interference fringes can be suppressed. For example, the “bank” refers to a support portion formed in the upper cladding layer in accordance with the height of the ridge portion, and for example, refers to a portion formed to protect the ridge portion from collision with the outside or stress at the time of bonding.

In one embodiment, the refractive index of the lower cladding layer is higher than the refractive index of the upper cladding layer, the surface of the light shielding groove is covered with an insulating layer, and the depth of the light shielding groove may reach an absorption layer that is either a substrate or a buffer layer formed on the substrate. That is, there may be a portion where the insulating layer and the absorption layer are in contact with or intersect with each other.

A portion of the light guided through the ridge portion is coupled to the bank and guided through the bank. In the asymmetric cladding in which the refractive index of the lower cladding layer is higher than the refractive index of the upper cladding layer, light guided through each of the ridge portion and the bank is attracted to the lower cladding layer side. In such a configuration, when the light shielding groove is shallow, the light emitted from the bank passes through a portion deeper than the light shielding groove, and interference fringes are formed in the FFP. The semiconductor laser device described above is configured such that the light shielding groove reaches the absorption layer, and light emitted from the end face of the bank is coupled to the insulating layer of the light shielding groove, guided through the insulating layer, and led to and absorbed by the absorption layer. As a result, it is possible to prevent light emitted from the bank from forming interference fringes. The absorption layer is a material that has a bandgap smaller than the bandgap of the active layer that determines the emission wavelength and absorbs laser light and stray light.

In one embodiment, the incident angle of a light ray with respect to the light shielding groove at the depth at which the intensity of a light beam peaks is greater than 0°. The incident angle is more preferably greater than 5°, still more preferably greater than 10°. The larger the incident angle, the larger the coupling to the insulating layer.

In one embodiment, the composition ratio of Al in the upper cladding layer may be higher than the composition ratio of Al in the lower cladding layer by 0.01 or more.

In one embodiment, the thickness of the lower cladding layer may be greater than the thickness of the upper cladding layer. As a result, it is possible to secure a clearance between the light guided through the ridge portion and the absorption layer, and it is possible to suppress a decrease in efficiency.

In one embodiment, the ridge portion may be widened in an emission region near the emission end face.

In one embodiment, the cross-sectional shape of the light shielding groove may be non-linear, in other words, curved on the bank side.

In one embodiment, the semiconductor substrate may be a GaAs substrate. In this case, in the case of light the oscillation wavelength of which is the red region, the GaAs substrate can be used as the absorption layer. Note that description that the light the oscillation wavelength of which is the red region is also simply described as that the oscillation wavelength is red or the like.

In one embodiment, an end portion of the light shielding groove in the width direction may protrude toward the ridge portion side with respect to a side of the bank facing the ridge portion. By bringing the end portion of the light shielding groove close to the ridge portion, stray light emitted from the bank can be more reliably shielded, and interference fringes can be suppressed.

An edge emitting type semiconductor laser device according to one embodiment includes a multilayer structure of a lower cladding layer, an active layer, and an upper cladding layer formed on a semiconductor substrate, a ridge portion formed in the upper cladding layer, a bank formed in the upper cladding layer so as to be adjacent to the ridge portion in a width direction, and a light shielding groove formed in the upper cladding layer so as to be adjacent to the bank in a waveguide direction. The refractive index of the lower cladding layer is higher than the refractive index of the upper cladding layer, and the end portion of the light shielding groove protrudes to the ridge portion side with respect to a side of the bank facing the ridge portion in the width direction.

By bringing the end portion of the light shielding groove close to the ridge portion, stray light emitted from the bank can be more reliably shielded, and interference fringes can be suppressed.

### Embodiment

Hereinafter, the present disclosure will be described with reference to the drawings on the basis of preferred embodiments. The same or equivalent components, members, and processing illustrated in the drawings are denoted by the same reference numerals, and redundant description is omitted as appropriate. In addition, the embodiments are not intended to limit the disclosure but examples, and all features described in the embodiments and combinations thereof are not necessarily essential to the disclosure.

Dimensions (thickness, length, width, and the like) of each member described in the drawings may be appropriately enlarged or reduced for easy understanding. Furthermore, the dimensions of the plurality of members do not necessarily indicate the magnitude relationship therebetween, and even when a certain member A is drawn thicker than another member B in the drawing, the member A may be thinner than the member B.

### Embodiment

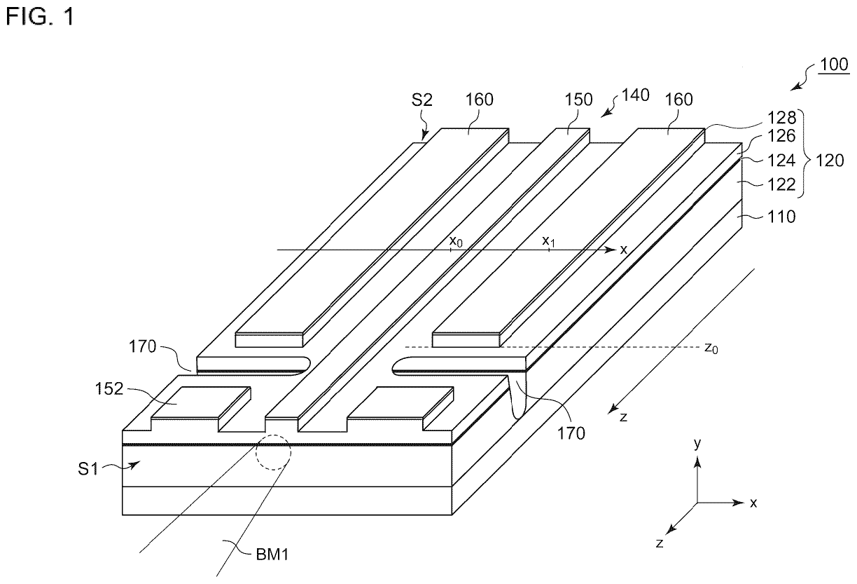

FIG. 1 is a perspective view of a semiconductor laser device 100 according to an embodiment. The semiconductor laser device 100 is of an edge emitting type, and emits laser light (beam) BM1 from an emission end face S1. A laser resonator 140 is formed between the emission end face S1 and a reflection end face S2 of the semiconductor laser device 100. S1 and S2 are also referred to as a front end face and a rear end face, respectively.

The laser resonator 140 is formed on a semiconductor substrate 110. A multilayer structure 120 including a lower cladding layer 122 that is an n-type cladding layer, an active layer 124, an upper cladding layer 126 that is a p-type cladding layer, and a p-type contact layer 128 is formed by crystal growth on the semiconductor substrate 110. In addition, although not illustrated in detail, there may be a (interface) layer that changes the composition stepwise in order to reduce a band notch between the upper cladding layer 126 and the contact layer 128. For example, in the case of a semiconductor laser having a red oscillation wavelength, AlGaInP is used for the cladding layer, and GaAs is used for the contact layer, and examples of the composition of the layer for reducing the band notch described above include AlGaInP and AlGaAs, and the Al composition can be changed stepwise or continuously.

The laser resonator 140 is formed using the multilayer structure 120. The upper cladding layer 126 is subjected to ridge machining for current constriction, and has a ridge portion 150. Although an electrode is required for the operation of the laser resonator 140, it is sufficient if the electrode is formed at an appropriate position using a known technique, and thus illustration is omitted.

In the drawing, the width direction of the laser resonator 140 is the x-axis, a direction perpendicular to the semiconductor substrate 110 is a y-axis, and a length direction of the laser resonator 140, that is, a waveguide direction of the laser light is a z-axis. In the present specification, the laser resonator 140 in plan view means the laser resonator 140 in plan view from a direction orthogonal to the semiconductor substrate 110, that is, viewing the laser resonator 140 along the y-axis. In addition, the emission end face S1 of the laser resonator 140 in front view means viewing the laser resonator 140 along the z-axis.

In addition, in the upper cladding layer 126, banks 160 are formed adjacent to the ridge portion 150 in the width direction (x-axis direction).

Further, in the upper cladding layer 126, light shielding grooves 170 are formed adjacent to the banks 160 in the waveguide direction (z-axis direction).

In the present embodiment, the laser resonator 140 has an asymmetric cladding structure, and a refractive index nₙ of the lower cladding layer 122 is higher than a refractive index np of the upper cladding layer 126. Specifically, the upper cladding layer 126 has a higher Al composition ratio than the lower cladding layer 122. For example, when the oscillation wavelength is red or infrared, (AlₓGa₍₁₋ₓ₎)_{0.5}In_{0.5}P is generally used for the cladding layer, and here, a structure in which the Al composition ratio x of the lower cladding layer 122 is lower than that of the upper cladding layer is referred to as an asymmetric cladding structure. In addition, the p-type upper cladding layer 126 is doped with impurities such as Mg, and the n-type lower cladding layer 122 is doped with impurities such as Si, for example, but, in order to obtain favorable characteristics, the impurity concentration of the upper cladding layer 126 is generally higher than the impurity concentration of the lower cladding layer 122.

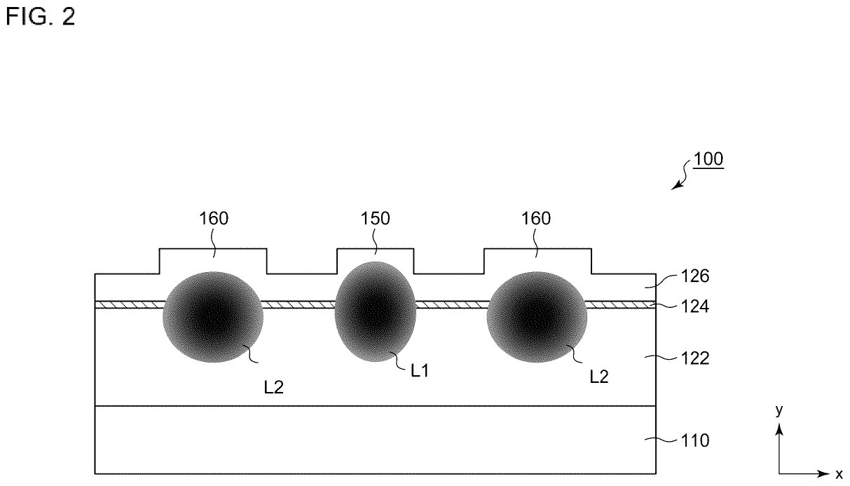

FIG. 2 is a diagram schematically illustrating beam intensity of the semiconductor laser device 100 of FIG. 1. This beam intensity indicates an intensity distribution in a plane perpendicular to the z-axis at the end portion (z=z₀) of the banks 160 in FIG. 1. Laser light L1 emitted as the beam BM1 is guided in a Z-axis direction immediately below the ridge portion 150. In addition, stray light L2 is also guided in the Z-axis direction immediately below the banks 160. As described above, since the semiconductor laser device 100 has an asymmetric structure in which the refractive index of the lower cladding layer 122 is higher than the refractive index of the upper cladding layer 126, the laser light L1 spreads more on the lower cladding layer 122 side. As a result, penetration of light to the upper cladding layer 126 is reduced, light absorption in GaAs used as the contact layer 128 and serving as an absorption layer can be reduced in a case where the oscillation wavelength is red or infrared, and there is an effect of increasing the slope efficiency of the current-light output characteristic. In addition, when the impurity concentration of the upper cladding layer 126 is higher than that of the lower cladding layer 122, a large amount of light is distributed to the lower cladding layer 122 having a lower impurity concentration, so that the internal loss caused by the free carrier loss can be reduced. In order to obtain favorable characteristics, the difference in Al composition ratio x between the upper cladding layer 126 and the lower cladding layer 122 is desirably 0.01 or more, and when the film thickness of the lower cladding layer 122 is appropriately set, the absorption of laser light by the absorption layer existing below the lower cladding layer 122 (substrate side) can be suppressed, and the difference in Al composition ratio x may be further increased (for example, 0.3 or more) to further increase the bias of light.

When the oscillation wavelength is red, a GaAs substrate may be used as the semiconductor substrate 110, and this absorbs red light. With such a configuration, when the thickness of the lower cladding layer 122 is thin, the laser light L1 is absorbed by the semiconductor substrate 110, and the efficiency decreases. Therefore, the thickness of the lower cladding layer 122 is preferably configured to be greater than the thickness of the upper cladding layer 126. It is sufficient if the material of the substrate is any material as long as it absorbs light having an oscillation wavelength, and may be, for example, an InP substrate or a GaN substrate.

The stray light L2 is also biased to the lower cladding layer 122 side similarly to the laser light L1.

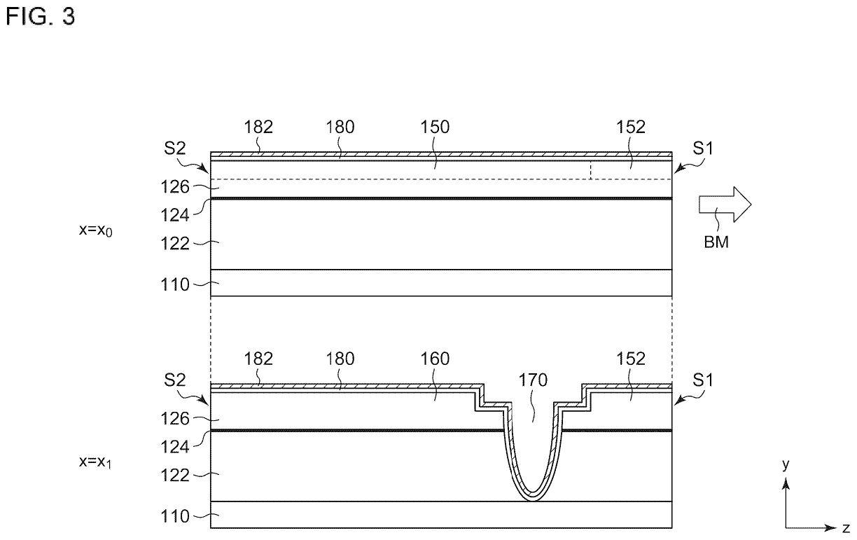

FIG. 3 is a cross-sectional view perpendicular to the x-axis of the semiconductor laser device 100 of FIG. 1. The upper part of FIG. 3 illustrates a cross section at a center (x=x₀) of the ridge portion 150 in the x-axis direction, and the lower part illustrates a cross section at a center (x=x₁) of the bank 160. The surface of the upper cladding layer 126 of the semiconductor laser device 100 is covered with an insulating film 180. The insulating film 180 also enters the light shielding groove 170, and the surface of the light shielding groove 170 is covered with the insulating film 180. Further, the insulating film 180 may be covered with a metal film 182.

As illustrated in FIG. 2, the stray light L2 is guided below the banks 160. The light shielding grooves 170 block the stray light L2 and prevent the stray light L2 from being emitted from the emission end face S1.

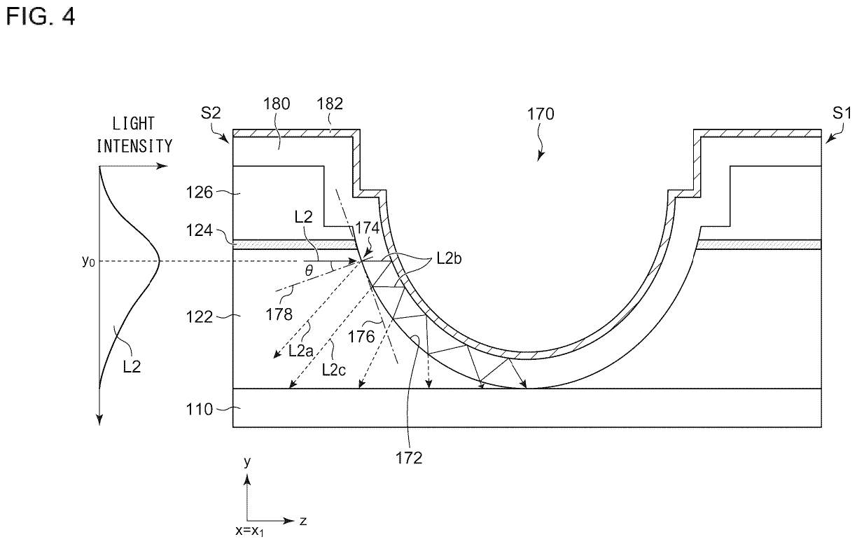

FIG. 4 is a diagram describing shielding of the stray light L2 by the light shielding groove 170. The left part of FIG. 4 illustrates an intensity distribution of the stray light L2 in a depth direction. In the cross-sectional view of FIG. 4, a light ray (principal light ray) of the stray light L2 having a depth y₀ at which the intensity is maximized is illustrated. An incident surface 172 of the light shielding groove 170 is formed non-parallel to an xy plane, and thus, the stray light L2 is incident non-perpendicularly to the incident surface 172 of the light shielding groove 170. Reference numeral 174 denotes an incident point, reference numeral 176 denotes a tangent line to the incident surface 172 at the incident point, and reference numeral 178 denotes a normal line to the incident surface 172 at the incident point. That is, an incident angle θ formed by the stray light L2 and the normal line 178 is larger than 0°. The incident angle θ is preferably 5° or more, and more preferably 10° or more. As the incident angle θ increases, the stray light L2 is more likely to be coupled to the insulating film 180.

At the incident point 174, part L2a of the stray light L2 is reflected by the insulating film 180 and directed to the semiconductor substrate 110 side. Since the bandgap of the semiconductor substrate 110 is smaller than the bandgap of the active layer 124 that determines the emission wavelength and the semiconductor substrate 110 is an absorption layer that absorbs the stray light L2, the reflected light L2a directed to the semiconductor substrate 110 is absorbed by the semiconductor substrate 110.

At the incident point 174, part L2b of the stray light L2 enters the insulating film 180 and is guided using the insulating film 180 as a waveguide. Since the insulating film 180 reaches the semiconductor substrate 110 that is an absorption layer, the light L2b guided in the insulating film 180 is absorbed by the semiconductor substrate 110 in the vicinity of the lowest portion of the light shielding groove 170.

Part L2c of the light L2b guided in the insulating film 180 can be emitted again from the insulating film 180 to the lower cladding layer 122, but this light L2c is directed to the semiconductor substrate 110 and thus absorbed by the semiconductor substrate 110.

When the metal film 182 is formed on the insulating film 180, the metal film 182 functions as a reflection film, so that it is possible to suppress the part L2c of the light L2b guided in the insulating film 180 from leaking to the light shielding groove 170 side.

However, the metal film 182 is not essential and may be omitted. In this case, leakage of light to the light shielding groove 170 side may be suppressed by a waveguide using a difference in refractive index between air and the insulating film 180.

With the semiconductor laser device 100, the stray light L2 guided through the bank 160 can be shielded in the light shielding groove 170, and the stray light L2 emitted from the emission end face S1 can be significantly reduced. As a result, the stray light L2 guided through the bank 160 and the laser light L1 guided through the ridge portion 150 can be suppressed from forming interference fringes in the far field, and a clear spot can be formed.

Advantages of the semiconductor laser device 100 are clarified by comparison with comparative art.

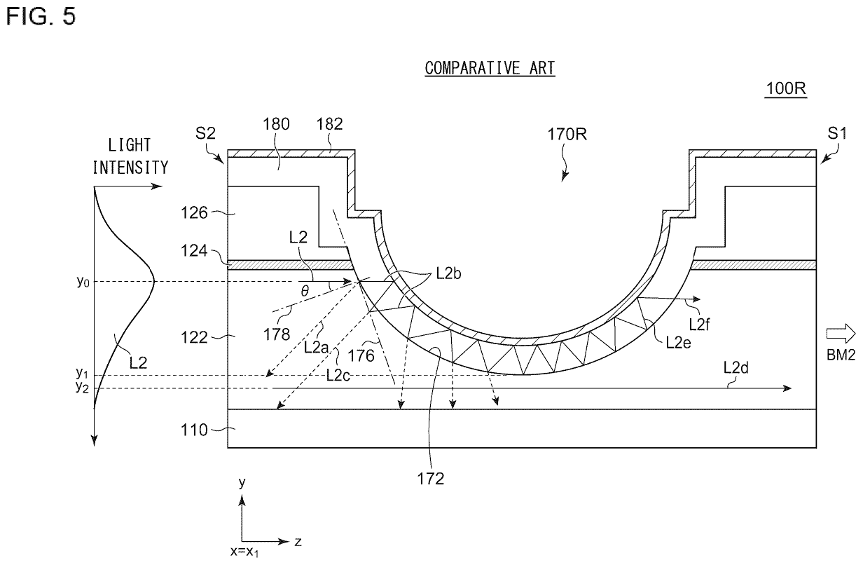

FIG. 5 is a cross-sectional view of a semiconductor laser device 100R according to comparative art. In the comparative art, a light shielding groove 170R does not reach a semiconductor substrate 110 that is an absorption layer. With this configuration, stray light L2d guided through a position y₂ lower than a depth y₁ of the lowest portion of the light shielding groove 170R can be guided to an emission end face S1 without being shielded by the light shielding groove and can be emitted from the emission end face S1.

In addition, part L2e of light L2b guided in an insulating film 180 is not absorbed by the semiconductor substrate 110 at the lowest portion of the light shielding groove 170R, and is guided to an emission end face side. The light L2e is emitted to the lower cladding layer 122 on the emission end face S1 side, and light L2f is emitted from the emission end face S1.

As described above, in the comparative art, a beam BM2 caused by stray light L2d and L2f is emitted and interferes with a beam BM1 in the far field, thereby forming an unclear light spot.

With the semiconductor laser device 100 according to the embodiment, the problem in the comparative art can be solved.

Next, modifications of the semiconductor laser device 100 will be described.

### First Modification

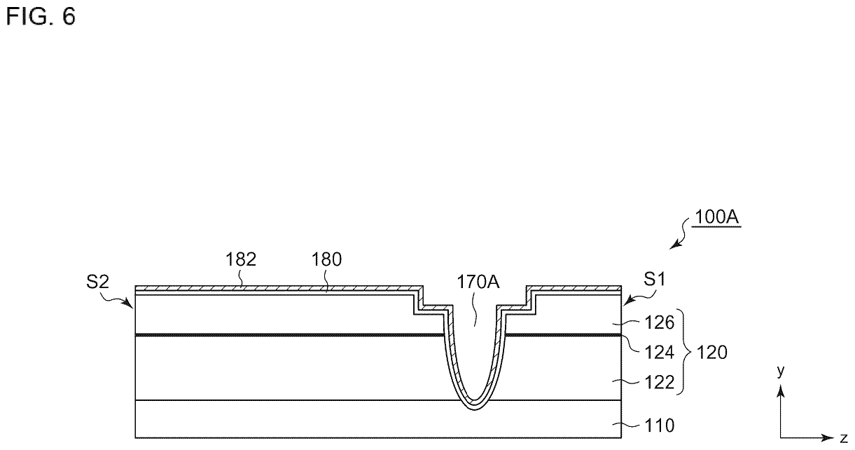

FIG. 6 is a cross-sectional view of a semiconductor laser device 100A according to a first modification. A light shielding groove 170A is dug deeper on a lower surface side than an upper interface of the semiconductor substrate 110. The other points are the same as those of the embodiment.

### Second Modification

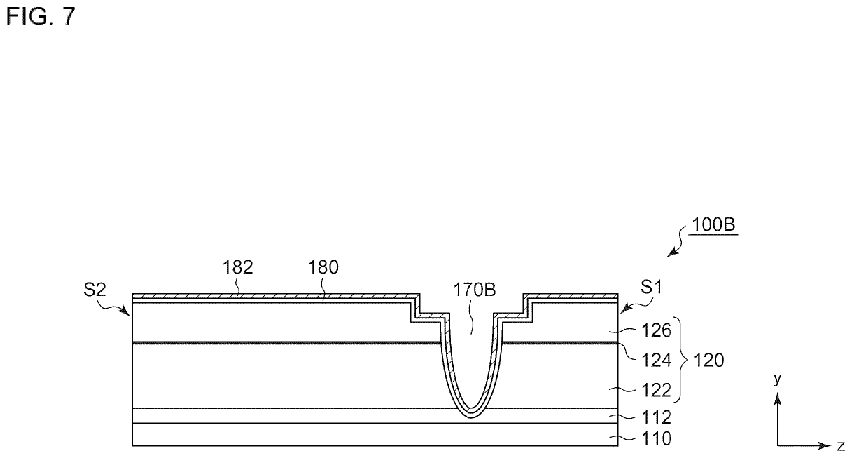

FIG. 7 is a cross-sectional view of a semiconductor laser device 100B according to a second modification. In this modification, for the purpose of enhancing the crystallinity of the multilayer structure 120, a buffer layer 112 is formed on the semiconductor substrate 110, and the multilayer structure 120 is formed on the buffer layer 112. Then, the buffer layer 112 is used as the absorption layer, and the depth of a light shielding groove 170B reaches the buffer layer 112. For example, GaAs is often used as the absorption layer when an emission wavelength region is a red region, but AlGaInP, AlGaAs, InP, or other group III-V semiconductor materials may be used as long as the material has a composition smaller than the bandgap of the active layer that determines the emission wavelength.

### Third Modification

Next, a modification of the cross-sectional shape of the light shielding groove 170 will be described.

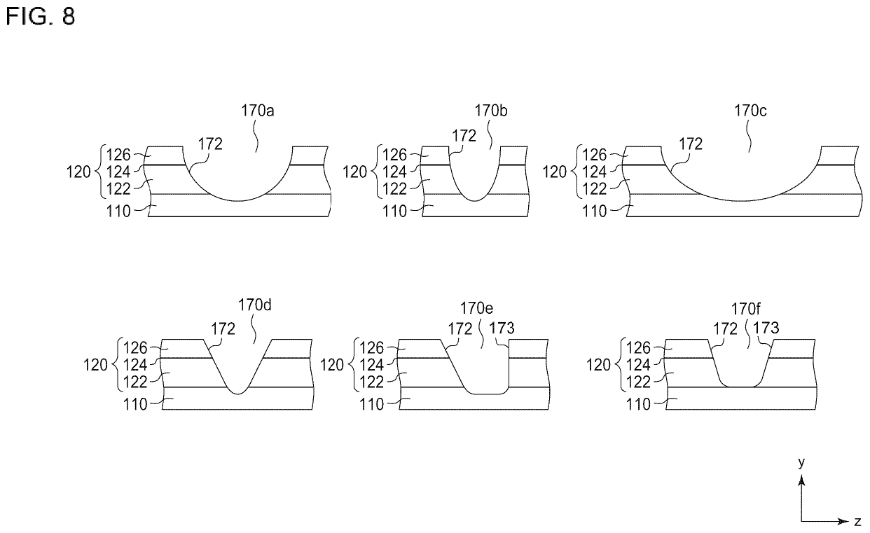

FIG. 8 is a view illustrating a modification of a cross-sectional shape of the light shielding groove 170 in a plane perpendicular to the x-axis. In the drawing, the right side (+z direction) is the emission end face S1, and the left side (−z direction) is the reflection end face S2. In each of light shielding grooves 170a to 170f, the incident surface 172 on the reflection end face S2 side is formed as a curved surface. The light shielding groove 170a has a shape along an arc. The light shielding grooves 170b and 170c have a shape along an ellipse, a depth direction (y-axis direction) of the light shielding groove 170b is a major axis of the ellipse, and the depth direction (y-axis direction) of the light shielding groove 170c is a minor axis of the ellipse.

In the light shielding groove 170d, the incident surface 172 is formed as a paraboloid.

The cross section of the light shielding groove 170 may be left-right asymmetric. Since there are no particular restrictions on the shape and inclination angle of an emission surface 173 of the light shielding groove 170, the emission surface 173 may be a substantially perpendicularly steep plane as illustrated in the light shielding groove 170e.

Like the light shielding groove 170f, the light shielding groove may be formed along a bathtub shape.

### Fourth Modification

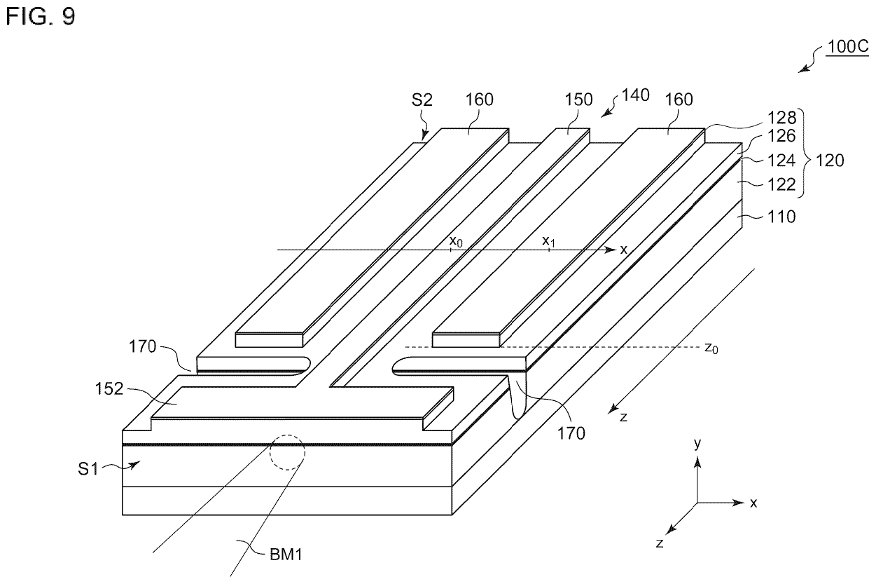

FIG. 9 is a perspective view of a semiconductor laser device 100 according to a fourth modification. The ridge portion 150 is widened in an emission region 152 near the emission end face S1. In this modification, the width of the ridge portion 150 of the emission region 152 is equal to the length from the end to the end of the two banks 160. Note that the width and shape of the emission region 152 are not limited to those in FIG. 9. The other points are the same as those of the embodiment.

### Fifth Modification

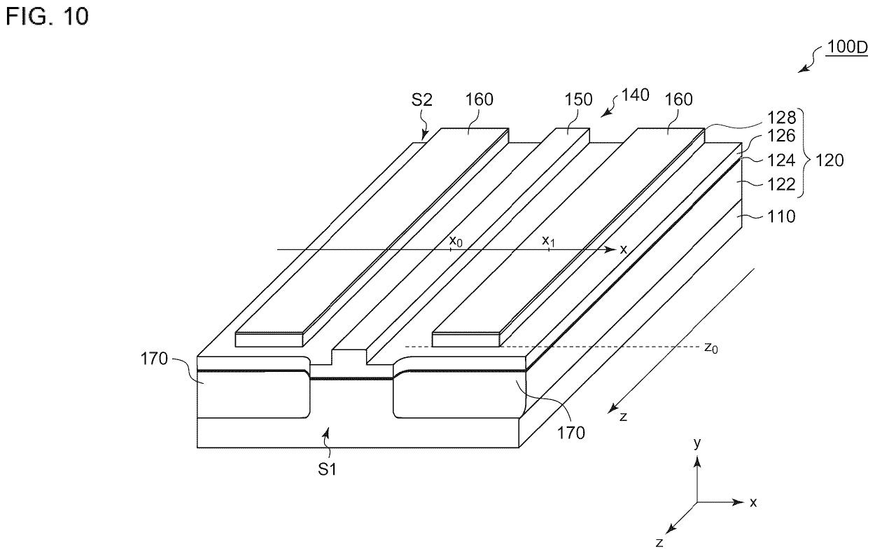

FIG. 10 is a perspective view of a semiconductor laser device according to a fifth modification. The light shielding grooves 170 are formed in contact with the emission end face S1. In this modification, the lowest portions of the light shielding grooves 170 are located on the emission end face S1, but it is sufficient if the light shielding grooves 170 are is formed in the vicinity of the emission end face S1 so as to prevent the stray light L2 guided through the banks 160 from being emitted from the emission end face S1, and the position in the Z-axis direction where the light shielding grooves 170 are formed is not limited to that in FIG. 10. The other points are the same as those of the embodiment.

In the above description, the features of the light shielding grooves 170 in the depth direction (y-axis direction) have been described. Next, a preferred structure of the light shielding grooves 170 in the x-axis direction (width direction of the resonator) will be described.

Three structures were examined for the length (width) of the light shielding grooves 170 in the x-axis direction.

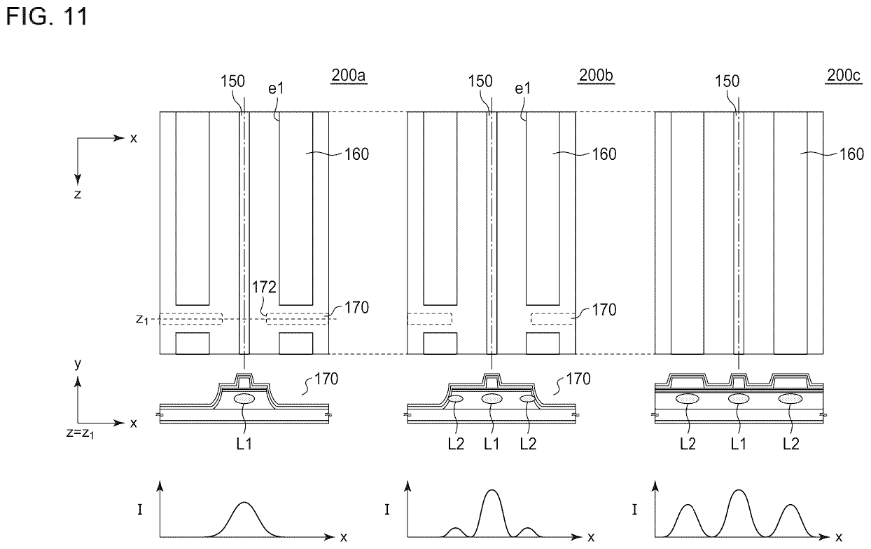

FIG. 11 is a diagram illustrating three structures 200a to 200c of the semiconductor laser device 100. For each of structures 200a to 200c, (i) a plan view, (ii) a cross-sectional view at z=z₁, and (iii) an intensity distribution (beam profile) of light in a horizontal direction (x-axis direction) at depth y0 at which the intensity is maximum are illustrated. In the cross-sectional view, beam patterns of the laser light L1 guiding through the ridge portion 150 and the stray light L2 guiding through the banks 160 are schematically illustrated.

In the first structure 200a, in the x-axis direction, the ends of the light shielding grooves 170 in the x-axis direction protrude to the ridge portion 150 side with respect to inner sides e1 of the banks 160. In this structure, the stray light L2 is shielded by the light shielding grooves 170.

In the second structure 200b, in the x-axis direction, the ends of the light shielding grooves 170 in the x-axis direction are located outside inner sides e1 of the banks 160. In this structure, part of the stray light L2 close to the ridge portion 150 remains without being completely shielded by the light shielding grooves 170.

The third structure 200c has a structure in which the light shielding grooves 170 are omitted.

The beam profile was calculated by simulation for each of the first to third structures 200a to 200c. Then, an error from the Gaussian distribution of each beam profile was calculated. The error was calculated by integrating the error between the intensity and the Gaussian distribution in the x-axis direction.

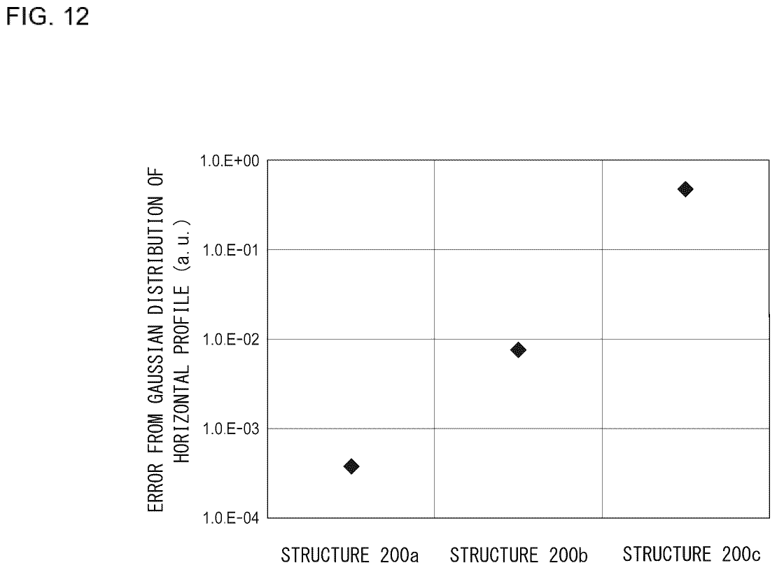

FIG. 12 is a diagram illustrating an error from the Gaussian distribution of a beam profile of each of the first to third structures 200a to 200c. In the structure 200a in which end portions 171 of the light shielding grooves 170 protrude to the ridge portion 150 side with respect to the sides e1 of the banks 160, the error from the Gaussian distribution is 3.9×10⁻⁴, and the error is very small. In the structure 200b in which end portions 171 of the light shielding grooves 170 are located outside the sides e1 of the banks 160, the error from the Gaussian distribution is 7.7×10⁻³, and the error is large. In the structure 200c in which the light shielding grooves 170 are not provided, the error is 4.6×10⁻¹, which is larger.

Comparing the structures 200a and 200b, the structure 200a has an error smaller by 1 digit or more. This means that the structure 200a can suppress interference fringes in the far-field as compared with the structure 200b.

The embodiments merely illustrate the principle and application of the present disclosure, and many modifications and changes in arrangement can be made to the embodiments without departing from the spirit of the present disclosure defined in the claims.

What is claimed is:

1. An edge emitting type semiconductor laser device, comprising:
a multilayer structure of a lower cladding layer, an active layer, and an upper cladding layer formed on a semiconductor substrate;
a ridge portion formed in the upper cladding layer;
a bank formed in the upper cladding layer so as to be adjacent to the ridge portion in a width direction; and
a light shielding groove formed in the upper cladding layer so as to be adjacent to the bank in a waveguide direction.

2. The semiconductor laser device according to claim 1, wherein
a refractive index of the lower cladding layer is higher than a refractive index of the upper cladding layer,
a surface of the light shielding groove is covered with an insulating layer, and a depth of the light shielding groove reaches an absorption layer that is either the substrate or a buffer layer formed on the substrate.

3. The semiconductor laser device according to claim 1, wherein an incident angle of a light ray with respect to the light shielding groove at a depth at which intensity of a light beam peaks is greater than 0°.

4. The semiconductor laser device according to claim 1, wherein a composition ratio of Al in the upper cladding layer is higher than a composition ratio of Al in the lower cladding layer by 0.01 or more.

5. The semiconductor laser device according to claim 1, wherein a thickness of the lower cladding layer is greater than a thickness of the upper cladding layer.

6. The semiconductor laser device according to claim 1, wherein the ridge portion is widened in an emission region near an emission end face.

7. The semiconductor laser device according to claim 1, wherein the light shielding groove is formed in contact with an emission end face.

8. The semiconductor laser device according to claim 1, wherein a cross-sectional shape of the light shielding groove in a resonator direction is non-linear on a bank side.

9. The semiconductor laser device according to claim 1, wherein the semiconductor substrate is a GaAs substrate.

10. The semiconductor laser device according to claim 1, wherein an end portion of the light shielding groove in a width direction protrudes to a ridge portion side with respect to a side of the bank facing the ridge portion.
